(19) United States
(12) Patent Application Publication
(10) Pub. No.: US 2008/0239206 A1
(43) Pub. Date: Oct. 2, 2008

(54) Ba-Sr-Ca CONTAINING COMPOUND AND WHITE LIGHT EMITTING DEVICE INCLUDING THE SAME

(75) Inventors: Kubota SHUNICHI, Yongin-si (KR); Young-sic KIM, Yongin-si (KR); Tae-gon KIM, Yongin-si (KR); Seoung-jae IM, Yongin-si (KR)

Correspondence Address: CANTOR COLBURN, LLP, 20 Church Street, 22nd Floor, Hartford, CT, 06103, US

(73) Assignee: SAMSUNG ELECTRO-MECHANICS CO., LTD., Suwon-si (KR)

(21) Appl. No.: 12/048,945

(22) Filed: Mar. 14, 2008

(30) Foreign Application Priority Data
Mar. 30, 2007 (KR) 10-2007-0031930

(51) Int. Cl. G02F 1/13357; B32B 15/04; C22C 30/00; H01L 33/00; H01J 1/62

(52) U.S. Cl. 349/69; 420/580; 428/457; 313/483; 257/98; 313/503; 257/E33.061

(57) ABSTRACT

Disclosed is a compound comprising Ba—Sr—Ca obtained by heat treating, under a reducing atmosphere, a starting material which is a blend comprising Ba oxide; Sr oxide; Ca oxide; an oxide of Eu, Mn, Sm, Sn, Sb, Ce, Pr, Nd, Gd, Tb, Dy, Ho, Er, Tm, Yb, or Bi; Mg oxide; and an oxide of Si or Ge; the blend being mixed together in a molar ratio of x:y:z:(7-x-y-z):a:b, where 0<x<7, 0<y<7, 0<z<7, 0.9<a<1.1 and 3.6<b<4.4, wherein the compound comprising Ba—Sr—Ca provides white luminescence when the compound comprising Ba—Sr—Ca is illuminated by ultraviolet or near-ultraviolet electromagnetic radiation.

This application claims priority to Korean Patent Application No. 10-2007-0031930, filed on Mar. 30, 2007, and all the benefits accruing therefrom under 35 U.S.C. §119, the contents of which in its entirety are hereby incorporated by reference.

### BACKGROUND

This disclosure relates to a compound comprising Ba—Sr—Ca and a white light emitting device (LED) comprising the compound comprising Ba—Sr—Ca.

White light emitting devices using semiconductors have gradually replaced some existing lighting devices because semiconductor based light emitting devices have longer lifespans, offer more compact size, and use lower driving voltages.

Currently, white light emitting devices are fabricated mainly by three methods. In a first method, three colored light emitting diodes are combined to generate homogeneous white light. In a second method, a yellow phosphor is excited using a blue LED as a light source to provide white light. In a third method, three color phosphors are excited using an ultraviolet (UV) light emitting diode (LED) to generate white light.

The first method, which uses three colored light emitting diodes, has several disadvantages, including high production costs, bulky device sizes because of the complexity of the driving circuitry, undesirable optical properties, and poor reliability due to differences in the color temperature of the three colored light emitting diodes.

The second method, which uses a blue LED to provide white light by exciting a yellow phosphor, has a higher luminous efficiency than the first method. However, applicability of this method is limited because of poor color rendering, thus this method is not suitable for some lighting applications for, e.g., hospitals or grocery stores.

The third method, which employs three color phosphors, has been a focus of recent research efforts on white luminesence because it can potentially accomodate high electrical current and potentially provides high color sensitivity.

One method for achieving white luminescence is to use a blend of red, green and blue (RGB) phosphors. Japanese Patent Applications 1999-33978 and 1999-261980 disclose composite-phase phosphors as white phosphors obtained by mixing a ZnS:Zn phosphor emitting blue light and a (ZnₓCd₁₋ₓ)S:Ag phosphor emitting yellow light in a predetermined ratio.

The color of light from composite-phase phosphors is unstable because considerable changes in color can result because of differences between the properties of deteriorated constituents of the composite-phase phosphor, ultimately resulting in luminosity degradation.

In more recent years, much attention has been paid to develop compounds providing white luminescence without using the RGB phosphor blend. Moreover, synthesizing red (R), green (G) and blue (B) phosphors separately requires different syntheses under different conditions, which can involve a complex manufacturing processes.

### BRIEF SUMMARY

Disclosed herein is a compound comprising barium-strontium-calcium (Ba—Sr—Ca), and a white light emitting device (LED) that comprises the compound comprising Ba—Sr—Ca. Disclosed herein too is the use of the compound comprising Ba—Sr—Ca as a white phosphor for producing white light having improved emission intensity, luminous efficiency and color purity. Disclosed herein too is a white light emitting device comprising the compound comprising Ba—Sr—Ca.

The compound comprising Ba—Sr—Ca is a compound that provides white luminescence. Compared to the synthesis of multiple phosphors, such as red, green and blue phosphors, disclosed embodiments can provide simplified manufacturing processes. The compound comprising Ba—Sr—Ca is a white phosphor having excellent emission intensity, light conversion efficiency, and color purity, and a light emitting device including the compound comprising Ba—Sr—Ca provides excellent emission intensity, light conversion efficiency, and color purity. Disclosed embodiments provide white luminescence when excited by ultraviolet or near-ultraviolet electromagnetic radiation.

Disclosed is a compound comprising Ba—Sr—Ca, the compound being obtained by heat-treating, under a reducing atmosphere, a starting material blend comprising Ba oxide; Sr oxide; Ca oxide; an oxide of Eu, Mn, Sm, Sn, Sb, Ce, Pr, Nd, Gd, Tb, Dy, Ho, Er, Tm, Yb, Bi, or a combination comprising at least one of the foregoing oxides; Mg oxide; and an oxide of Si or Ge, the starting material blend comprising the foregoing oxides in a molar ratio of x:y:z:(7-x-y-z):a:b, wherein x represents the number of moles of barium, y represents the number of moles of strontium, z represents the number of moles of calcium, (7-x-y-z) represents the number of moles of Eu, Mn, Sm, Sn, Sb, Ce, Pr, Nd, Gd, Tb, Dy, Ho, Er, Tm, Yb, Bi, or a combination thereof, a represents the number of moles of Mg and b represents the number of moles of Si or Ge; wherein 0<x<7, 0<y<7, 0<z<7, 0.9<a<1.1 and 3.6<b<4.4; wherein the x, y, and z are simultaneously not 0, wherein the sum of x, y and z is less than 7, and wherein the compound comprising Ba—Sr—Ca provides white luminescence when the compound comprising Ba—Sr—Ca is illuminated by ultraviolet or near-ultraviolet electromagnetic radiation.

The compound comprising Ba—Sr—Ca, as disclosed in an exemplary embodiment, provides uniform, strong emission intensity over a wide range of excitation wavelengths when illuminated by ultraviolet (UV) or near-ultraviolet light. In addition, the compound comprising Ba—Sr—Ca has high luminous efficiency and color purity, therefore it is advantageously useful as a white phosphor. Accordingly, a white light emitting device including the compound comprising Ba—Sr—Ca can simplify manufacturing processes, compared to processes where it is necessary to separately synthesize three phosphors, i.e., a red (R) phosphor, a green (G) phosphor, and a blue (B) phosphor, to prepare a RGB phosphor blend. Furthermore, a white light emitting device including the compound comprising Ba—Sr—Ca can provide excellent white light.

Also disclosed in an alternative embodiment is a white light emitting device, the device comprising an ultraviolet light emitting diode and a white phosphor comprising a compound comprising Ba—Sr—Ca. The white light emitting device can further comprise a red phosphor.

Also disclosed in an alternative embodiment is a lamp, the lamp comprising a mercury, xenon or self-emissive lamp and a white light emitting device, the device comprising a white phosphor, the phosphor comprising a compound comprising Ba—Sr—Ca.

Also disclosed in an alternative embodiment is a method of preparing a phosphor, the method comprising mixing in a molar ratio of x:y:z:(7-x-y-z):a:b, wherein x represents the number of moles of barium, y represents the number of moles of strontium, z represents the number of moles of calcium, (7-x-y-z) represents the number of moles of Eu, Mn, Sm, Sn, Sb, Ce, Pr, Nd, Gd, Tb, Dy, Ho, Er, Tm, Yb, Bi, or a combination thereof, a represents the number of moles of Mg and b represents the number of moles of Si or Ge, Ba oxide; Sr oxide; Ca oxide; an oxide of Eu, Mn, Sm, Sn, Sb, Ce, Pr, Nd, Gd, Tb, Dy, Ho, Er, Tm, Yb, or Bi; Mg oxide; and an oxide of Si or Ge, the blend comprising BaO:SrO:CaO:EuO, MnO, SmO, SnO, SbO, CeO_{1.5}, PrO_{1.5}, NdO_{1.5}, GdO_{1.5}, TbO_{1.5}, DyO_{1.5}, HoO_{1.5}, ErO_{1.5}, TmO_{1.5}, YbO_{1.5}, BiO_{1.5}:MgO:SiO₂ or GeO₂, where 0<x<7, 0<y<7, 0<z<7, 0.9<a<1.1 and 3.6<b<4.4, to form a starting material blend; and heat-treating the starting material blend under a reducing atmosphere to yield a phosphor.

Also described in an alternative embodiment is a method of illumination, the method comprising assembling a white light emitting device, the device comprising an ultraviolet (UV) light emitting diode (LED) and a white phosphor comprising a compound comprising Ba—Sr—Ca; and illuminating the white phosphor with ultraviolet light from the ultraviolet light emitting diode so that the white phosphor emits white light.

### BRIEF DESCRIPTION OF THE DRAWINGS

The above and other aspects and advantages of the disclosed embodiments will become more apparent by describing in detail exemplary embodiments thereof with reference to the attached drawings in which:

FIG. 1 is a schematic illustration of changes in the crystal structure of an exemplary compound comprising Ba—Sr—Ca as a function of synthesis temperature;

FIG. 2 is a schematic diagram of an exemplary LED;

FIG. 3 is an emission spectrum that illustrates emission spectra of exemplary compounds comprising Ba—Sr—Ca. Illustrated too is the emission spectrum for a RGB phosphor blend;

FIG. 4 is a chromaticity coordinate diagram that shows the chromaticity of an exemplary compound comprising Ba—Sr—Ca. Illustrated too is the chromaticity for a RGB phosphor blend;

FIG. 5 is graph that illustrates the emission intensities of exemplary compounds comprising Ba—Sr—Ca relative to the emission intensity of a RGB phosphor blend;

FIG. 6 illustrates emission spectra of exemplary compounds comprising Ba—Sr—Ca and a comparative compound that comprises a RGB phosphor blend;

FIG. 7 is a chromaticity coordinate diagram that shows the chromaticity of exemplary compounds comprising Ba—Sr—Ca; and

FIG. 8 is a phase diagram that illustrates the mixing molar ratios of starting materials for exemplary compounds comprising Ba—Sr—Ca and the emission intensities of the exemplary compounds comprising Ba—Sr—Ca.

### DETAILED DESCRIPTION

Disclosed embodiments will now be described more fully with reference to the accompanying drawings, in which exemplary embodiments are shown.

It will be understood that when an element is referred to as being “on” another element, it can be directly on the other element or intervening elements can be present therebetween. In contrast, when an element is referred to as being “disposed on” or “formed on” another element, the elements are understood to be in at least partial contact with each other, unless otherwise specified.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements and the thicknesses of layers and regions are exaggerated for clarity.

Disclosed herein is a compound comprising Ba—Sr—Ca that is obtained by heat treating in a reducing atmosphere a starting material which is a blend comprising Ba oxide; Sr oxide; Ca oxide; an oxide of Eu, Mn, Sm, Sn, Sb, Ce, Pr, Nd, Gd, Tb, Dy, Ho, Er, Tm, Yb, or Bi or the like, or a combination comprising at least one of the foregoing oxides; Mg oxide; and an oxide of Si or Ge, the blend comprising BaO:SrO:CaO:EuO, MnO, SmO, SnO, SbO, CeO_{1.5}, PrO_{1.5}, NdO_{1.5}, GdO_{1.5}, TbO_{1.5}, DyO_{1.5}, HoO_{1.5}, ErO_{1.5}, TmO_{1.5}, YbO_{1.5}, BiO_{1.5}:MgO:SiO₂, or GeO₂, or the like, or a combination comprising at least one of the foregoing oxides, being mixed together in a molar ratio of x:y:z:(7-x-y-z):a:b, wherein x represents the number of moles of barium, y represents the number of moles of strontium, z represents the number of moles of calcium, (7-x-y-z) represents the number of moles of Eu, Mn, Sm, Sn, Sb, Ce, Pr, Nd, Gd, Tb, Dy, Ho, Er, Tm, Yb, Bi, or a combination thereof, a represents the number of moles of Mg and b represents the number of moles of Si or Ge, where 0<x<7, 0<y<7, 0<z<7, 0.9<a<1.1 and 3.6<b<4.4, wherein the compound comprising Ba—Sr—Ca provides white luminescence when the compound comprising Ba—Sr—Ca is illuminated by ultraviolet or near-ultraviolet electromagnetic radiation.

In another embodiment, disclosed is a compound comprising Ba—Sr—Ca that is obtained by heat treating in a reducing atmosphere a starting material which is a blend comprising Ba oxide; Sr oxide; Ca oxide; an oxide of Eu, Mn, Sm, Sn, Sb, Ce, Pr, Nd, Gd, Tb, Dy, Ho, Er, Tm, Yb, or Bi or the like, or a combination comprising at least one of the foregoing oxides; Mg oxide; and an oxide of Si or Ge, the starting material blend comprising one of the foregoing oxides in a molar ratio of x:y:z:(7-x-y-z):a:b, wherein x represents the number of moles of barium, y represents the number of moles of strontium, z represents the number of moles of calcium, (7-x-y-z) represents the number of moles of Eu, Mn, Sm, Sn, Sb, Ce, Pr, Nd, Gd, Tb, Dy, Ho, Er, Tm, Yb, Bi, or a combination thereof, a represents the number of moles of Mg and b represents the number of moles of Si or Ge, where 0<x<7, 0<y<7, 0<z<7, 0.9<a<1.1 and 3.6<b<4.4, wherein the compound comprising Ba—Sr—Ca provides white luminescence when the compound comprising Ba—Sr—Ca is illuminated by ultraviolet or near-ultraviolet electromagnetic radiation.

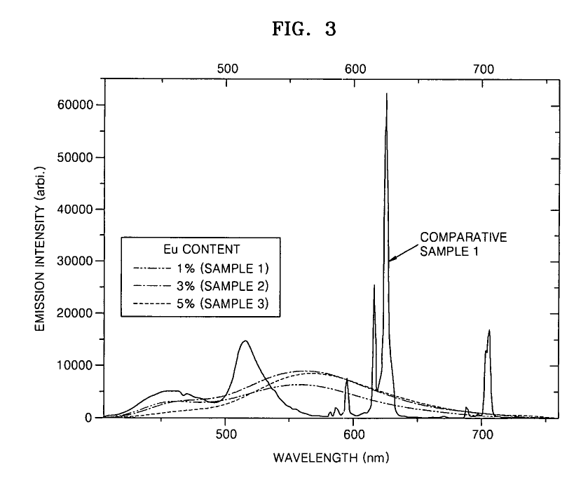

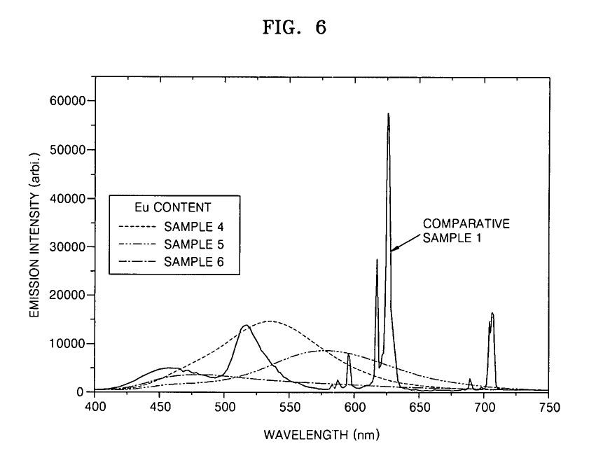

The compound comprising Ba—Sr—Ca emits intense light uniformly over a very broad wavelength region ranging from a blue wavelength region to a red wavelength region, and white light is achieved through emission over multiple wavelengths as is illustrated in FIGS. 3 and 6. In addition, the color temperatures over which white luminescence is displayed by the compound comprising Ba—Sr—Ca can be adjusted by varying the weight of barium, strontium or calcium to the total weight of the sum of barium, calcium and strontium in the compound comprising Ba—Sr—Ca.

In one embodiment, the reducing atmosphere can be comprised of hydrogen, nitrogen, argon, helium or ammonia. In an exemplary embodiment, the reducing atmosphere is a mixture of hydrogen and nitrogen.

As described above the compound comprising Ba—Sr—Ca unexpectedly provides white luminescence when the compound is illuminated by ultraviolet or near-ultraviolet electromagnetic radiation. Therefore, the compound comprising Ba—Sr—Ca has an absorption at a wavelength of about 390 nm to about 460 nm and can be advantageously used as a commercial white phosphor when excited using ultraviolet light. In an alternative embodiment, the compound comprising Ba—Sr—Ca has an absorption between about 200 nm and about 460 nm.

White light emission wavelengths can be defined by color temperature. In an embodiment, the compound comprising Ba—Sr—Ca unexpectedly produces white light with a color temperature ranging from about 3000 K to about 6500 K, specifically 3500 K to about 6000 K, more specifically about 4000 K to about 5500 K.

Although the chemical formula, empirical formula, molecular formula (if applicable) or crystal structure of the compound comprising Ba—Sr—Ca are still unknown, unexpectedly it has been discovered that the compound comprising Ba—Sr—Ca is a material emitting white light. It has hitherto been known that compounds comprising Ba—Sr—Ca have a Bredigite type crystal structure and emit green light. However, to date there have not been any reports of a compound comprising Ba—Sr—Ca capable of emitting white light. Based on the fact that the compound comprising Ba—Sr—Ca is a white light emitting material, while not wanting to be bound by theory, it can be concluded that the compound comprising Ba—Sr—Ca is a novel compound.

While not wanting to be bound by theory as to the mechanism of white luminescence by the compound comprising Ba—Sr—Ca, the inventors suggest two possibilities. First, the compound comprising Ba—Sr—Ca presumably has a new chemical formula that is different from that of a previously known compound comprising Ba—Sr—Ca. Second, the compound comprising Ba—Sr—Ca presumably has a crystal structure different from the known Bredigite structure. Particularly, for the second possibility, even if the compound comprising Ba—Sr—Ca has the same empirical or molecular formula as other known Ba—Sr—Ca formulations, because it provides white luminescence it must have a crystal structure that is distinctly different from the other formulations that emit green light.

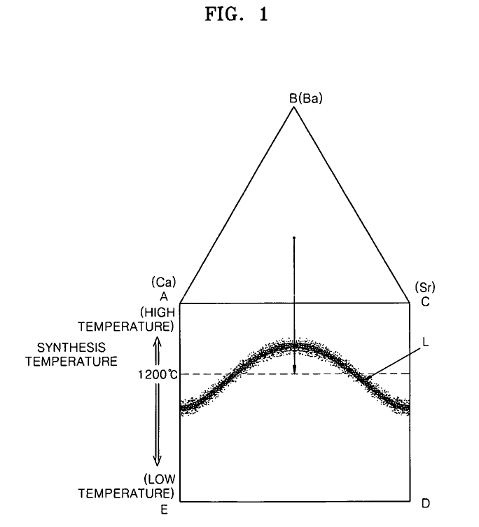

While not wanting to be bound by theory, the crystal structure of the compounds comprising Ba—Sr—Ca can result from the synthesis temperature, as will now be described with reference to FIG. 1.

FIG. 1 is a schematic illustration of changes in the crystal structure of the compounds that comprise Ba—Sr—Ca as a function of synthesis temperature.

Referring to FIG. 1, triangle ABC represents a phase diagram. The vertices of a triangle ABC represent Ba, Sr or Ca content in a compound containing only Ba, Sr, or Ca, respectively. A point on a side of triangle ABC represents a compound comprised of the elements represented by the two vertices connected. A point within triangle ABC represents a compound comprised of the elements represented by the vertices, i.e. Ba, Sr and Ca. The relative distance between a point inside the triangle ABC and the midpoint of a side of triangle ABC indicates the relative content of the element represented by the vertex opposite the side selected. Accordingly, a ratio of distances between a point inside the triangle ABC and each side of the triangle ABC indicates the relative molar ratio of Ba, from a Ba containing compound, Sr, from a Sr containing compound, and Ca, from a Ca containing compound in the ternary compound represented by the point selected. In this way, the molar ratios of Ba, Sr or Ca in a compound comprising Ba, Sr, and Ca can be determined at every point inside the triangle ABC. In other words, each point inside the triangle ABC represents a blend of a Ba containing compound, a Sr containing compound, and a Ca containing compound useful for preparing the compound comprising Ba—Sr—Ca, with its particular Ba—Sr—Ca molar ratio.

With reference once again to the FIG. 1, when crystal structures of the synthesized compounds comprising Ba—Sr—Ca are defined by the intersections of vertical lines extending downward from selected points inside the triangle ABC and horizontal lines extending from selected points indicating synthesis temperatures on the left or vertical axis, a crystal structure distribution of the Ba—Sr—Ca containing compounds is expected to form within rectangle ACDE as illustrated in FIG. 1. That is, compounds comprising Ba—Sr—Ca having a known crystal structure (e.g., the Bredigite structure) are produced in an area above a curve L inside the rectangle ACDE, and compounds comprising Ba—Sr—Ca having a new crystal structure are produced in an area below the curve L inside the rectangle ACDE.

In more detail, in the rectangle ACDE illustrated in FIG. 1, compounds comprising Ba—Sr—Ca are distributed in the area below the curve L, and comparative Ba—Sr—Ca containing compounds, which are known green light-emitting materials, are distributed in the area above the curve L.

While not wanting to be bound by theory, a starting material for forming the compound comprising Ba—Sr—Ca can be expressed as oxide because any carbonate, nitrate, nitride, chloride, halide, hydroxide, or the like, when used as the starting material, will oxidize and be converted into oxide at some point in the formation process. In addition to metal oxides, any type of carbonate, nitrate, nitride, nitride oxide, halide, chloride, or hydroxide starting material, or the like, or a combination comprising one of the foregoing starting materials, can be used as long as the mixing molar ratio is kept at an appropriate level. For example, instead of a Ba containing oxide, BaCO₃, BaCl₂, Ba(NO₃)₂, or Ba(OH)₂ may be used as the starting material. Likewise, instead of a Sr containing oxide, SrCO₃, SrCl₂, Sr(NO₃)₂, or Sr(OH)₂ may be used as the starting material. Further, instead of Ca containing oxide, CaCO₃, CaCl₂, Ca(NO₃)₂, or Ca(OH)₂ may be used as the starting material. Examples of compounds that can be used instead of the oxide of Eu, Mn, Sm, Sn, Sb, Ce, Pr, Nd, Gd, Tb, Dy, Ho, Er, Tm, Yb or Bi, include Eu₂(CO₃)₃, Eu(NO₃)₃, EuCl₃, MnCO₃, MnCl₂, Mn(NO₃)₂, Sm(NO₃)₃, SmCl₃, SnCl₂, SnCl₄, SbCl₃, CeCl₃, Ce(NO₃)₃, Ce(OH)₄, Pr₂(CO₃)₃, Pr(NO₃)₃, PrCl₃, Nd₂(CO₃)₃, Nd(NO₃)₃, NdCl₃, Gd₂(CO₃)₃, Gd(NO₃)₃, GdCl₃, Tb₂(CO₃)₃, Tb(NO₃)₃, TbCl₃, Dy₂(CO₃)₃, Dy(NO₃)₃, DyCl₃, Ho₂(CO₃)₃, Ho(NO₃)₃, HoCl₃, Er₂(CO₃)₃, Er(NO₃)₃, ErCl₃, Tm₂(CO₃)₃, Tm(NO₃)₃, TmCl₃, Yb₂(CO₃)₃, Yb(NO₃)₃, YbCl₃, and so on. Instead of Mg oxide, Mg₂CO₃, MgCl, MgNO₃, or MgOH can also be used.

As described above, the compound comprising Ba—Sr—Ca is prepared by heat-treating in a reducing atmosphere, a starting material blend comprising Ba oxide; Sr oxide; Ca oxide; an oxide of Eu, Mn, Sm, Sn, Sb, Ce, Pr, Nd, Gd, Tb, Dy, Ho, Er, Tm, Yb, or Bi; Mg oxide; and an oxide of Si or Ge. For example, the compound comprising Ba—Sr—Ca can be prepared by sintering the blend at a temperature of about 900° C. to about 1400° C., specifically about 1000° C. to about 1300° C., and more specifically about 1100° C. to about 1200° C. for about 1 to about 20 hours, specifically about 3 hours to about 10 hours, and more specifically about 5 hours to about 8 hours.

In an embodiment, the rare earth compound comprises an oxide of Eu, Mn, Sm, Sn, Sb, Ce, Pr, Nd, Gd, Tb, Dy, Ho, Er, Tm, Yb, Bi, or a combination comprising at least one of the foregoing rare earth metals and functions as an activator when the compound comprising Ba—Sr—Ca provides white luminescence. Preferably, the oxide is Eu₂O₃.

In addition, SiO₂ is preferably used as the Si oxide.

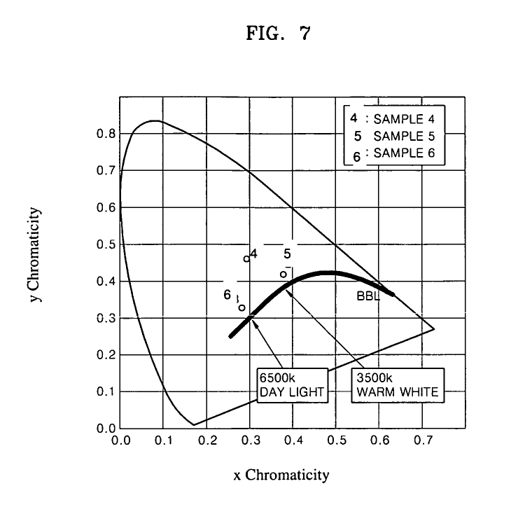

The compound comprising Ba—Sr—Ca can be used as a white phosphor. In particular, unlike previously known white phosphors that have a weak emission intensity in a wavelength region of approximately 550 nm, the compound comprising Ba—Sr—Ca has a uniform distribution in the emission intensity over a very wide wavelength range as is illustrated in FIGS. 3 and 7, suggesting that the compound comprising Ba—Sr—Ca can be advantageously used as a white phosphor. The compound comprising Ba—Sr—Ca emits white light having a relatively high color temperature in a red emission wavelength area. Accordingly, the compound comprising Ba—Sr—Ca can be advantageously used in white light illumination applications, such as providing illumination for hospitals, groceries, museums, and the like.

In one embodiment, the compound comprising Ba—Sr—Ca can be used in an ultraviolet light emitting diode (LED).

In an alternative embodiment, the white phosphor compound comprising Ba—Sr—Ca can be incorporated in a light emitting device including a light emitting diode. The light emitting device can be applied to traffic lights, backlights for communication devices or other display devices, and the like, and can also be used as substitutes for light sources in next-generation illumination applications.

In a preferred alternative embodiment, an excitation light source, such as an ultraviolet light emitting diode, provides electromagnetic radiation in the ultraviolet or near-ultraviolet wavelength region. Preferably, the excitation wavelength of the electromagnetic radiation in the ultraviolet or near-ultraviolet wavelength region is between about 200 nm and about 460 nm, specifically 390 nm to 460 nm.

In an alternative embodiment, the white light emitting device can further comprise a red phosphor in addition to the white phosphor. In this case, since the white light emitting device can emit light with a higher color rendering index (CRI), it can be advantageously used for illumination applications, such as surgical operating rooms, groceries, museums, and the like.

Usable examples of the red phosphor include Y₂O₃:Eu³⁺,Bi³⁺(Sr,Ca,Ba,Mg,Zn)₂P₂O₇:Eu²⁺,Mn²⁺; (Ca,Sr,Ba,Mg,Zn)₁₀(PO₄)₆(F,Cl,Br,OH):Eu²⁺,Mn²⁺; (Gd,Y,Lu,La)₂O₃:Eu³⁺,Bi³⁺; (Gd,Y,Lu,La)₂O₂S:Eu³⁺,Bi³⁺; (Gd,Y,Lu,La)BO₃:Eu³⁺,Bi³⁺; (Gd,Y,Lu,La)(P,V)O₄:Eu³⁺,Bi³⁺; (Ca,Sr)S:Eu²⁺; CaLa₂S₄:Ce³⁺; (Ba,Sr,Ca)MgP₂O₇:Eu²⁺,Mn²⁺; (Y,Lu)₂WO₆:Eu³⁺,Mo⁶⁺; (Ba,Sr,Ca)ₓSi_{y}N_{z}:Eu²⁺(0.5≦x≦3.1, 5≦y≦8, 0<z≦3); (Sr,Ca,Ba,Mg,Zn)₂SiO₄:Eu²⁺,Mn²⁺, or the like, or a combination comprising at least one of the foregoing phosphors.

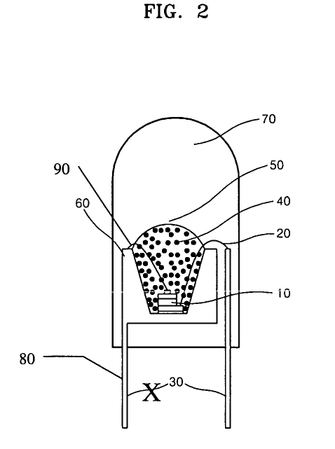

FIG. 2 is a schematic diagram of a white light emitting device according to an embodiment, illustrating a surface-mounted light emitting device of a polymer lens type. Here, an epoxy lens is used as an exemplary polymer lens.

Referring to FIG. 2, a chip-type ultraviolet light emitting diode (LED) 10 is connected to electric lead wires 30 and 80 through gold wires 20 and 90, respectively. The LED 10 can emit electromagnetic radiation in the ultraviolet or near-ultraviolet wavelength region. In an embodiment, the white phosphor 40 is included in epoxy mold layer 50. A detailed description of white phosphor 40 is the same as described above. The ultraviolet or near-ultraviolet electromagnetic radiation emitted from the LED 10 can excite the white phosphor 40 contained in the epoxy mold layer 50, thereby emitting white light. The epoxy mold layer 50 can comprise epoxy-based resin, and can be a general-purpose resin that is commercially available. In addition, the inside of a forming mold 60, as is shown in FIG. 2, is formed of a reflective film coated with aluminum or silver, thereby upwardly reflecting the ultraviolet or near-ultraviolet radiation emitted from LED 10, and trapping an appropriate amount of epoxy.

An epoxy dome lens 70 is formed at an upper portion of the epoxy mold layer 50 and can vary in its shape according to the orientation angle desired.

In an embodiment, the structure of the white light emitting device is not limited to that shown in FIG. 2 and can be one of various types of LED structures, including a phosphor-mounting type, a shell type, a PCB surface mounting type, and so on.

In an alternative embodiment the white phosphor can also be applied to a lamp, such as a mercury lamp or a xenon lamp, or a self-emissive LCD, in addition to the disclosed white light emitting device.

The following examples are merely illustrative, and should not be construed to be any sort of limitation on the scope of the invention.

### SYNTHESIS EXAMPLE 1

### Using 1 mol % Eu Contained in the Starting Material Blend

BaCO₃, 5.65 grams (g), SrCO₃, 4.23 g, CaCO₃, 2.87 g, Eu₂O₃, 0.31 g, MgO, 0.5 g and SiO₂, 2.98 g, were mixed to give a starting material blend. The blend had had a Ba:Sr:Ca molar ratio of 1:1:1 while containing Eu in an amount of 1 mol %. The blend was placed in an alumina crucible that was then placed in an electric furnace. Then, the resultant blend was heat-treated in a reducing atmosphere of 5% H₂ and 95% N₂, at a temperature of approximately 1200° C. for approximately 5 hours. The obtained sintered product was crushed to yield a powder, rinsed with distilled water, and finally dried in an oven at 100° C. to obtain a white phosphor (SAMPLE 1).

### SYNTHESIS EXAMPLE 2

### Using 3 mol % Eu Contained in the Starting Material Blend

A white phosphor (SAMPLE 2) was obtained in the same manner as in Synthesis Example 1, except that a blend containing 5 g of BaCO₃, 7.48 g of SrCO₃, 2.54 g of CaCO₃, 0.41 g of Eu₂O₃, 0.45 g of MgO and 2.69 g of SiO₂, was used as a starting material. The blend had a Ba:Sr:Ca molar ratio of 1:2:1, and Eu was contained in the blend in an amount of 3 mol %.

### SYNTHESIS EXAMPLE 3

### Using 5 mol % Eu Contained in the Starting Material Blend

A white phosphor (SAMPLE 3) was obtained in the same manner as in Synthesis Example 1, except that a blend containing 6.68 g of BaCO₃, 5 g of SrCO₃, 6.78 g of CaCO₃, 0.55 g of Eu₂O₃, 0.6 g of MgO and 3.60 g of SiO₂, was used as a starting material. The blend had a Ba:Sr:Ca molar ratio of 1:1:2, and Eu was contained in the blend in an amount of 5 mol %.

### SYNTHESIS EXAMPLE 4

### Mixing with Ba:Sr:Ca Molar Ratio of 4:1:1

A white phosphor (SAMPLE 4) was obtained in the same manner as in Synthesis Example 1, except that a blend containing 11.08 g of BaCO₃, 2.07 g of SrCO₃, 1.40 g of CaCO₃, 0.92 g of Eu₂O₃, 0.5 g of MgO and 2.98 g of SiO₂, was used as a starting material, and the blend had a Ba:Sr:Ca molar ratio of 4:1:1.

### SYNTHESIS EXAMPLE 5

### Mixing with Ba:Sr:Ca Molar Ratio of 1:4:1

A white phosphor (SAMPLE 5) was obtained in the same manner as in Synthesis Example 1, except that a blend containing 2.77 g of BaCO₃, 8.29 g of SrCO₃, 1.40 g of CaCO₃, 0.92 g of Eu₂O₃, 0.5 g of MgO and 2.98 g of SiO₂, was used as a starting material, and the blend had a Ba:Sr:Ca molar ratio of 1:4:1.

### SYNTHESIS EXAMPLE 6

### Mixing with Ba:Sr:Ca Molar Ratio of 1:1:4

A white phosphor (SAMPLE 6) was obtained in the same manner as in Synthesis Example 1, except that a blend containing 2.77 g of BaCO₃, 2.07 g of SrCO₃, 5.62 g of CaCO₃, 0.92 g of Eu₂O₃, 0.5 g of MgO and 2.98 g of SiO₂, was used as a starting material, and the blend had a Ba:Sr:Ca molar ratio of 1:1:4.

### COMPARATIVE EXAMPLE 1

La₂O₂S:Eu³⁺ (manufactured by Kasei) as a red phosphor, BAM:Eu²⁺,Mn²⁺ (manufactured by Kasei) as a green phosphor, and Sr₅(PO₄)₃Cl:Eu²⁺ (manufactured by Nemoto) as a blue phosphor were mixed to prepare a COMPARATIVE SAMPLE 1, which produced a day-light color white light with a color temperature of about 5000 K when illuminated by a light emitting device.

### EXAMPLES 1-6

### Preparation of a White LED

The compounds synthesized in Synthesis Examples 1-6 were used as white phosphors and a ultraviolet LED, with wavelength of about 390 nm, was used as an excitation light source, in the fabrication of a white LED conforming to that shown in FIG. 2.

FIG. 3 illustrates emission spectra of SAMPLES 1 through 3, which are Compound comprising Ba—Sr—Ca according to exemplary embodiments, and COMPARATIVE SAMPLE 1.

As is shown in FIG. 3, unlike the conventional white phosphor synthesized in Comparative Example 1 (COMPARATIVE SAMPLE 1), the white phosphors synthesized in Synthesis Examples 1-3 (SAMPLES 1-3) have uniform, strong emission intensities in a wavelength region ranging from below 520 nm to above 620 nm.

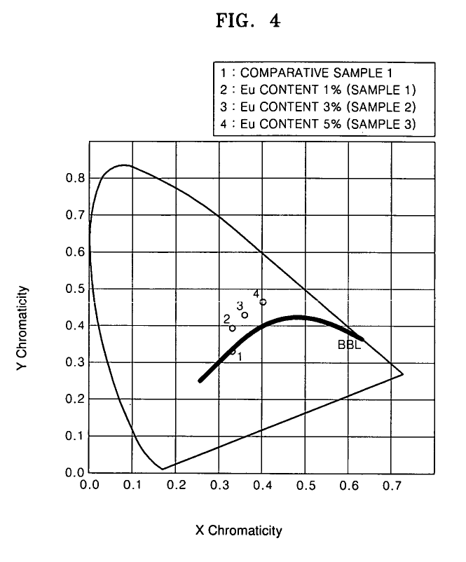

FIG. 4 is a chromaticity coordinate diagram. The location of the compound comprising Ba—Sr—Ca according to exemplary embodiments, specifically SAMPLES 4-6, and a conventional red-green-blue (RGB) phosphor blend, specifically Comparative SAMPLE 1, are indicated on the diagram. In FIG. 4, a line corresponding to a black body that completely absorbs light, without reflection, at various temperatures is given by the black body locus (BBL). The color on the BBL is considered to be white, and the white color gradually changes in a directional fashion along the BBL, in such a way that it appears as reddish white on the right and bluish white in the left of the chromaticity coordinate diagram. As confirmed from FIG. 4, surprisingly the chromaticity coordinates of SAMPLES 1 through 3 are located adjacent to the BBL, suggesting that commercially advantageous white luminescence can be provided.

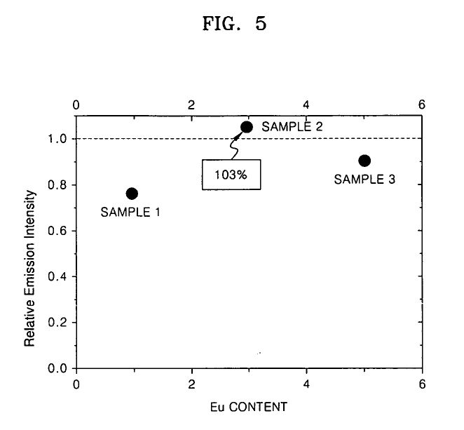

FIG. 5 illustrates the emission intensity from the compound comprising Ba—Sr—Ca, according to exemplary embodiments, specifically SAMPLES 1-3, relative to a conventional RGB phosphor blend synthesized in Comparative Example 1, specifically COMPARATIVE SAMPLE 1, based on the emission spectrum shown in FIG. 3. Here, the integral of the emission spectrum represents the emission intensity of a phosphor. As the integral of the emission spectrum increases, the phosphor becomes more efficient. As confirmed in FIG. 5, unexpectedly, SAMPLES 1-3 have emission intensities high enough to be put into commercialization as white phosphors.

FIG. 6 illustrates emission spectra of the compound comprising Ba—Sr—Ca according to exemplary embodiments, specifically SAMPLES 4-6, and the RGB phosphor blend synthesized in Comparative Example 1, specifically, COMPARATIVE SAMPLE 1. As confirmed from FIG. 6, unlike the white phosphor represented by COMPARATIVE SAMPLE 1, which has weak emission intensity in a wavelength region ranging from 520 nm to 620 nm, the white phosphors of the exemplary embodiments exemplified by SAMPLES 4-6 have uniform and strong emission intensities in the wavelength region ranging from about 520 nm to about 620 nm.

FIG. 7 illustrates chromaticity coordinates of the compound comprising Ba—Sr—Ca according to exemplary embodiments, specifically SAMPLES 4-6. Referring to FIG. 7, like SAMPLES 1-3 shown in FIG. 4, surprisingly the chromaticity coordinates of SAMPLES 4-6 are located adjacent to the BBL, therefore commercially advantageous white luminescence can be provided.

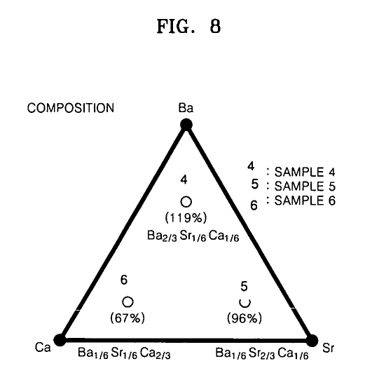

FIG. 8 is a ternary Ba—Sr—Ca phase diagram that illustrates the mixing molar ratios of starting materials with respect to the compound comprising Ba—Sr—Ca according to exemplary embodiments, specifically, SAMPLES 4-6, and the emission intensities of the Compound comprising Ba—Sr—Ca. In FIG. 8, numerical values in parentheses indicate the emission intensity of SAMPLES 4-6, relative to the total emission intensity of a RGB phosphor blend synthesized in Comparative Example 1, specifically, COMPARATIVE SAMPLE 1, as shown in FIG. 5. As confirmed in FIG. 8, SAMPLES 4-6 have emission intensities high enough to be put into commercialization as white phosphors.

As described above, the compound comprising Ba—Sr—Ca provides uniform, strong emission intensity when using a wide range of excitation wavelengths in the ultraviolet (UV) or near-ultraviolet wavelength region. In addition, the compound comprising Ba—Sr—Ca has high luminous efficiency and color purity, so that it is advantageously useful as a white phosphor. Accordingly, in an embodiment, a white light emitting device that comprises the compound comprising Ba—Sr—Ca can have a simpler manufacturing process compared to manufacturing processes where it is necessary to separately synthesize three phosphors, i.e., a red (R) phosphor, a green (G) phosphor, and a blue (B) phosphor to prepare a RGB phosphor blend. Furthermore, a white light emitting device that comprises the compound comprising Ba—Sr—Ca can provide white light having excellent color purity.

While disclosed embodiments have been shown and described with reference to exemplary embodiments thereof, it will be understood by those of ordinary skill in the art that various changes in form and details may be made therein without departing from the spirit and scope of the present invention as defined by the following claims.

In addition, many modifications can be made to adapt a particular situation or material to the teachings disclosed herein without departing from the essential scope thereof. Therefore, it is intended that this disclosure not be limited to the particular embodiments disclosed as the best mode contemplated for carrying out this invention, but that the disclosure will include all embodiments falling within the scope of the appended claims.

Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A compound comprising Ba—Sr—Ca, the compound being obtained by:
heat-treating, under a reducing atmosphere, a starting material blend comprising Ba oxide; Sr oxide; Ca oxide; an oxide of Eu, Mn, Sm, Sn, Sb, Ce, Pr, Nd, Gd, Tb, Dy, Ho, Er, Tm, Yb, Bi, or a combination comprising at least one of the foregoing oxides; Mg oxide; and an oxide of Si or Ge, the starting material blend comprising the foregoing oxides in a molar ratio of x:y:z:(7-x-y-z):a:b, wherein x represents the number of moles of barium, y represents the number of moles of strontium, z represents the number of moles of calcium, (7-x-y-z) represents the number of moles of Eu, Mn, Sm, Sn, Sb, Ce, Pr, Nd, Gd, Tb, Dy, Ho, Er, Tm, Yb, Bi, or a combination thereof, a represents the number of moles of Mg and b represents the number of moles of Si or Ge; wherein 0<x<7, 0<y<7, 0<z<7, 0.9<a<1.1 and 3.6<b<4.4; wherein the x, y, and z are simultaneously not 0, wherein the sum of x, y and z is less than 7, and wherein the compound comprising Ba—Sr—Ca provides white luminescence when the compound comprising Ba—Sr—Ca is illuminated by ultraviolet or near-ultraviolet electromagnetic radiation.

2. The compound comprising Ba—Sr—Ca of claim 1, wherein the white luminescence has a color temperature ranging from about 3000 K to about 6500 K.

3. The compound comprising Ba—Sr—Ca of claim 2, wherein the white luminescence has a color temperature ranging from about 3000 K to about 6000 K.

4. The compound comprising Ba—Sr—Ca of claim 1, wherein the heat-treatment is performed by sintering the blend at a temperature in a range from about 1000° C. to about 1300° C. for about 3 hours to about 10 hours.

5. The compound comprising Ba—Sr—Ca of claim 1, wherein the oxide of Eu, Mn, Sm, Sn, Sb, Ce, Pr, Nd, Gd, Tb, Dy, Ho, Er, Tm, Yb, or Bi is EuO or EuO_{1.5}, and the oxide of Si or Ge is SiO₂.

6. The compound comprising Ba—Sr—Ca of claim 1, wherein the oxide of Eu, Mn, Sm, Sn, Sb, Ce, Pr, Nd, Gd, Tb, Dy, Ho, Er, Tm, Yb, or Bi is Eu₂O₃, and the oxide of Si or Ge is SiO₂.

7. The Ba—Sr—Ca containing compound of claim 1, wherein the compound comprising Ba—Sr—Ca is used as a white phosphor.

8. A white light emitting device comprising:
an ultraviolet (UV) light emitting diode (LED); and
a white phosphor comprising the compound comprising Ba—Sr—Ca of claim 1.

9. The white light emitting device of claim 8, wherein an excitation light emitted by the ultraviolet light emitting diode is ultraviolet (UV) or near-ultraviolet (near-UV) electromagnetic radiation.

10. The white light emitting device of claim 9, wherein the wavelength of the electromagnetic radiation in the ultraviolet or near-ultraviolet wavelength region is between 390 nm to 460 nm.

11. The white light emitting device of claim 8, further comprising a red phosphor.

12. The white light emitting device of claim 11, wherein the red phosphor comprises at least one selected from the group consisting of Y₂O₃:Eu³⁺,Bi³⁺(Sr,Ca,Ba,Mg,Zn)₂P₂O₇:Eu²⁺,Mn²⁺; (Ca,Sr,Ba,Mg,Zn)₁₀(PO₄)₆(F,Cl,Br,OH):Eu²⁺,Mn²⁺; (Gd,Y,Lu,La)₂O₃:Eu³⁺,Bi³⁺; (Gd,Y,Lu,La)₂O₂S:Eu³⁺,Bi³⁺; (Gd,Y,Lu,La)BO₃:Eu³⁺,Bi³⁺; (Gd,Y,Lu,La)(P,V)O₄:Eu³⁺,Bi³⁺; (Ca,Sr)S:Eu²⁺; CaLa₂S₄:Ce³⁺; (Ba,Sr,Ca)MgP₂O₇:Eu²⁺,Mn²⁺; (Y,Lu)₂WO₆:Eu³⁺,Mo⁶⁺; (Ba,Sr,Ca)ₓSi_{y}N_{z}:Eu²⁺(0.5≦x≦3.1, 5≦y≦8, 0<z≦3); (Sr,Ca,Ba,Mg,Zn)₂SiO₄:Eu²⁺, Mn²⁺; and combinations thereof.

13. The white light emitting device of claim 8, wherein the white light emitting device is used for traffic lights, and backlights or light sources for communication devices or display devices.

14. A lamp comprising a white light emitting device, the device comprising:
a white phosphor, the phosphor comprising a compound comprising Ba—Sr—Ca.

15. A self-emissive LCD comprising a white light emitting device, the device comprising:
a white phosphor, the phosphor comprising a compound comprising Ba—Sr—Ca.

16. The lamp of claim 14, further comprising an ultraviolet light emitting diode.

17. The lamp of claim 14, further comprising a red phosphor, the red phosphor comprising at least one selected from the group consisting of Y₂O₃:Eu³⁺,Bi³⁺(Sr,Ca,Ba,Mg,Zn)₂P₂O₇:Eu²⁺,Mn²⁺; (Ca,Sr,Ba,Mg,Zn)₁₀(PO₄)₆(F,Cl,Br,OH):Eu²⁺,Mn²⁺; (Gd,Y,Lu,La)₂O₃:Eu³⁺,Bi³⁺; (Gd,Y,Lu,La)₂O₂S:Eu³⁺,Bi³⁺; (Gd,Y,Lu,La)BO₃:Eu³⁺,Bi³⁺; (Gd,Y,Lu,La)(P,V)O₄:Eu³⁺,Bi³⁺; (Ca,Sr)S:Eu²⁺; CaLa₂S₄:Ce³⁺; (Ba,Sr,Ca)MgP₂O₇:Eu²⁺,Mn²⁺; (Y,Lu)₂WO₆:Eu³⁺,Mo⁶⁺; (Ba,Sr,Ca)ₓSi_{y}N_{z}:Eu²⁺(0.5≦x≦3.1, 5≦y=8, 0<z≦3); (Sr,Ca,Ba,Mg,Zn)₂SiO₄:Eu²⁺,Mn²⁺; and combinations thereof.

18. A method of preparing a phosphor, the method comprising:
mixing in a molar ratio of x:y:z:(7-x-y-z):a:b, wherein x represents the number of moles of barium, y represents the number of moles of strontium, z represents the number of moles of calcium, (7-x-y-z) represents the number of moles of Eu, Mn, Sm, Sn, Sb, Ce, Pr, Nd, Gd, Tb, Dy, Ho, Er, Tm, Yb, Bi, or a combination thereof, a represents the number of moles of Mg and b represents the number of moles of Si or Ge,
Ba oxide; Sr oxide; Ca oxide; an oxide of Eu, Mn, Sm, Sn, Sb, Ce, Pr, Nd, Gd, Tb, Dy, Ho, Er, Tm, Yb, or Bi; Mg oxide; and an oxide of Si or Ge, the blend comprising BaO:SrO:CaO:EuO, MnO, SmO, SnO, SbO, CeO_{1.5}, PrO_{1.5}, NdO_{1.5}, GdO_{1.5}, TbO_{1.5}, DyO_{1.5}, HoO_{1.5}, ErO_{1.5}, TmO_{1.5}, YbO_{1.5}, BiO_{1.5}:MgO:SiO₂ or GeO₂, where 0<x<7, 0<y<7, 0<z<7, 0.9<a<1.1 and 3.6<b<4.4, to form a starting material blend; and
heat-treating the starting material blend under a reducing atmosphere to yield a phosphor.

19. The method of claim 17, further comprising:
crushing the phosphor;
rinsing the phosphor with distilled water; and
drying the phosphor in an oven to yield a white phosphor.

20. The method of claim 17, wherein the reducing atmosphere is a comprised of one or more gases selected from the group hydrogen, helium, nitrogen, argon, and ammonia.

21. A method of illumination comprising:
assembling a white light emitting device, the device comprising an ultraviolet (UV) light emitting diode (LED) and a white phosphor comprising a compound comprising Ba—Sr—Ca; and
illuminating the white phosphor with ultraviolet light from the ultraviolet light emitting diode so that the white phosphor emits white light.
